(19) United States
(12) Patent Application Publication
(10) Pub. No.: US 2026/0105216 A1
(43) Pub. Date: Apr. 16, 2026

(54) MODEL TRAINING METHOD AND APPARATUS

(71) Applicant: CHINA UNIVERSITY OF PETROLEUM—BEIJING, Beijing (CN)

(72) Inventors: Sanyi YUAN, Beijing (CN); Zhiqiang DING, Beijing (CN); Renjun XIE, Beijing (CN); Yanwu XU, Beijing (CN); Jianxiang FENG, Beijing (CN)

(21) Appl. No.: 19/038,752

(22) Filed: Jan. 28, 2025

(30) Foreign Application Priority Data
Oct. 12, 2024 (CN) 202411426405.1

(51) Int. Cl. G06F 30/27; E21B 41/00

(52) U.S. Cl. CPC G06F 30/27; E21B 41/00; E21B 2200/20; E21B 2200/22

(57) ABSTRACT

The present application provides a model training method and an apparatus, relating to the field of model training technologies. The model training method includes: pre-processing a drilling parameter of an explored well, a logging parameter of the explored well, and a drilling parameter of a target drilling well; constructing a first velocity model according to the pre-processed logging parameter of the explored well; obtaining a predictive drilling parameter according to the pre-processed drilling parameter of the target drilling well and the pre-processed drilling parameter of the explored well; and performing a first-level iterative optimization on the first velocity model according to the predictive drilling parameter and seismic data of the explored well and the target drilling well.

### CROSS-REFERENCE TO RELATED APPLICATIONS

This application claims priority to Chinese Patent Application No. 202411426405.1, filed on Oct. 12, 2024 and entitled “MODEL TRAINING METHOD AND APPARATUS”, which is hereby incorporated by reference in its entirety.

### TECHNICAL FIELD

The present application relates to the field of model training technologies and, in particular, to a model training method and an apparatus.

### BACKGROUND

It is crucial to construct a velocity model during a drilling process. The constructed velocity model can help predict velocity characteristics of underground rock strata, and such predictions can enhance drilling efficiency and safety. By optimizing drilling parameters and adjusting the pressure and rotational velocity of a drill bit, drilling costs can be reduced and potential geological hazards are avoided. At the same time, the velocity model also has a crucial effect on determining wellbore stability, identifying oil and gas reservoir locations and designing appropriate wellbore trajectories.

At present, a model construction manner in which logging data and seismic horizon data are combined is mainly adopted in the construction of the velocity model. Such approach of constructing the velocity model according to existing logging data and seismic horizon data is simple and easy to use, but it is difficult in this approach to fully capture geological changes near wells to be drilled in areas with strong heterogeneity of underground media and a small number of adjacent wells and scanty logging data, resulting in low prediction accuracy.

### SUMMARY

The present application provides a model training method and an apparatus, to address the problem of low accuracy due to data scarcity in using a velocity model constructed in the prior art for areas with strong heterogeneity of underground media and a small number of adjacent wells, and scanty logging data.

In a first aspect, an embodiment of the present application provides a model training method, including:
pre-processing a drilling parameter of an explored well, a logging parameter of the explored well, and a drilling parameter of a target drilling well, where the pre-processing includes data outlier processing and data smoothing filtering;
constructing a first velocity model according to the pre-processed logging parameter of the explored well;
obtaining a predictive drilling parameter according to the pre-processed drilling parameter of the target drilling well and the pre-processed drilling parameter of the explored well; and
performing a first-level iterative optimization on the first velocity model according to the predictive drilling parameter and seismic data of the explored well and the target drilling well.

In an implementation, a target optimization is any one optimization within the first-level iterative optimization;
for the target optimization, the performing the first-level iterative optimization on the first velocity model according to the predictive drilling parameter and the seismic data of the explored well and the target drilling well, includes:
optimizing the first velocity model according to the seismic data of the explored well and the target drilling well, and taking an optimization result as a second velocity model; and
optimizing the second velocity model according to the predictive drilling parameter, and taking an optimization result as a first velocity model after the target optimization.

In an implementation, before optimizing the second velocity model according to the predictive drilling parameter and taking the optimization result as the first velocity model after the target optimization, the method further includes:
establishing a mapping relationship between the predictive drilling parameter and a predictive velocity parameter according to a data analysis approach and a machine learning algorithm;
for any one optimization, the optimizing the second velocity model according to the predictive drilling parameter, includes:
obtaining the predictive velocity parameter according to the predictive drilling parameter and the mapping relationship; and
optimizing the second velocity model according to the predictive velocity parameter.

In an implementation, the obtaining the predictive velocity parameter according to the predictive drilling parameter and the mapping relationship, includes:
obtaining the predictive velocity parameter corresponding to the predictive drilling parameter through a prediction formula indicated by the mapping relationship, where the prediction formula is:

$${V}_{pred} = F ( {P}_{t + h} )$$

where, V_{pred} is the predictive velocity parameter, F( ) is a trained time-series intelligent model, and Pₜ₊ₕ is the predictive drilling parameter.

In an implementation, the optimizing the second velocity model according to the predictive velocity parameter, includes:
obtaining an optimized second velocity model through a second velocity model update formula according to the predictive velocity parameter and the second velocity model, where the second velocity model update formula is:

$${V}_{2} = initial ( {V}_{1} , {V}_{pred} )$$

where, V₂ is the optimized second velocity model, V₁ is the second velocity model, V_{pred} is the predictive velocity parameter, and initial is an update process of the second velocity model.

In an implementation, the optimizing the first velocity model according to the seismic data of the explored well and the target drilling well, and taking the optimization result as the second velocity model, includes:
obtaining the second velocity model through a first velocity model update formula according to the seismic data and the first velocity model, where the first velocity model update formula is:

$${V}_{1} = seismic ( V )$$

where, V₁ is the second velocity model, V is the first velocity model, and seismic is an update process of the first velocity model.

In an implementation, the obtaining the predictive drilling parameter according to the pre-processed drilling parameter of the target drilling well and the pre-processed drilling parameter of the explored well, includes:
obtaining the predictive drilling parameter through an ahead-of-bit prediction formula indicated by a time-series forecasting model, according to pre-processed drilling parameters at a plurality of time points of the target drilling well, and the pre-processed drilling parameter of the explored well, where the ahead-of-bit prediction formula is:

$${P}_{t + h} = F ( {P}_{t} , {P}_{t - 1} , … , {P}_{t - n} , H )$$

where, Pₜ₊ₕ is the predictive drilling parameter, F( ) is the time-series forecasting model, Pₜ is a pre-processed drilling parameter of the target drilling well at a current time point, Pₜ₋₁ is a pre-processed drilling parameter of the target drilling well at a time point relative to which the current time point has passed one time point, Pₜ₋ₙ is a pre-processed drilling parameter of the target drilling well at a time point relative to which the current time point has passed n time points, and H is the pre-processed drilling parameter of the explored well.

In an implementation, the constructing the first velocity model according to the pre-processed logging parameter of the explored well, includes:
obtaining a first velocity parameter according to the pre-processed logging parameter of the explored well, and performing low-pass filtering processing on the first velocity parameter through a low-pass filtering formula so as to obtain a second velocity parameter, where the low-pass filtering formula is:

$${V}_{low} ( f ) = \{ \begin{matrix}V ( f ) , & if \vert f \vert \leq {f}_{c} \\ 0 , & if \vert f \vert > {f}_{c}\end{matrix}$$

where, V_{low}(f) is the second velocity parameter, V(f) is the first velocity parameter, and f_{c} is a cut-off frequency; and
obtaining an interpolated velocity parameter according to the second velocity parameter, and obtaining the first velocity model according to the interpolated velocity parameter.

In an implementation, the obtaining the interpolated velocity parameter according to the second velocity parameter, includes:
obtaining the interpolated velocity parameter through an interpolation formula according to the second velocity parameter, where the interpolation formula is:

$$V ( x , y , z ) = {\sum }_{j = 1}^{n} {λ}_{j} {V}_{j}$$

where, V(x, y, z) is the interpolated velocity parameter, n is an amount of control points, Vⱼ is the second velocity parameter, λⱼ is an interpolation weight obtained through a weight formula, where the weight formula is:

$$\{ \begin{matrix}{\sum }_{j = 1}^{n} {λ}_{j} γ ( {d}_{ij} ) + μ = γ ( {d}_{i 0} ) \\ {\sum }_{j = 1}^{n} {λ}_{j} = 1\end{matrix}$$

where, γ(dᵢⱼ) is a semi-variogram of spatial correlation between the control points in a velocity parameter curve, γ(dᵢ₀) is a semi-variogram of spatial correlation between the control points and points to be interpolated in the velocity parameter curve, μ is a Lagrange number, and n is the amount of the control points.

In a second aspect, an embodiment of the present application provides a model training apparatus, including:
a pre-processing module configured to pre-process a drilling parameter of an explored well, a logging parameter of the explored well, and a drilling parameter of a target drilling well, where the pre-processing includes data outlier processing and data smoothing filtering;
a first velocity model construction module configured to construct a first velocity model according to the pre-processed logging parameter of the explored well;
an ahead-of-bit prediction module configured to obtain a predictive drilling parameter according to the pre-processed drilling parameter of the target drilling well and the pre-processed drilling parameter of the explored well; and
a velocity model iteration optimization module configured to perform a first-level iterative optimization on the first velocity model according to the predictive drilling parameter and seismic data of the explored well and the target drilling well.

In a third aspect, an embodiment of the present application provides an electronic device, including: a processor and a memory in communication connection with the processor; where
the memory stores computer-executable instructions; and
the processor executes the computer-executable instructions stored in the memory, so as to implement the model training method provided in the first aspect of the present application.

In a fourth aspect, an embodiment of the present application provides a computer-readable storage medium, where the computer-readable storage medium stores computer-executable instructions, so as to implement the model training method provided in the first aspect of the present application.

In a fifth aspect, an embodiment of the present application provides a computer program product, including a computer program, where when the computer program is executed by a processor, the model training method provided in the first aspect of the present application is implemented.

The present application provides a model training method and an apparatus, and the model training method includes: pre-processing the drilling parameter of the explored well, the logging parameter of the explored well, and the drilling parameter of the target drilling well, where the pre-processing includes data outlier processing and data smoothing filtering; constructing the first velocity model according to the pre-processed logging parameter of the explored well; obtaining the predictive drilling parameter according to the pre-processed drilling parameter of the target drilling well and the pre-processed drilling parameter of the explored well; and performing the first-level iterative optimization on the first velocity model according to the predictive drilling parameter and the seismic data of the explored well and the target drilling well. According to the above-described method, the following technical effects have been achieved: on the basis of constructing the first velocity model, the seismic data is added, and the seismic data mainly focuses on the heterogeneous characteristics of the strata during this process, and the changes in the strata can be described more finely through the introduction of the seismic data, especially with the support of amplitude information. Therefore, by using the seismic data to modify and optimize the first velocity model, the prediction accuracy of the velocity model in the areas with strong heterogeneity of the underground media can be improved. On the basis of the seismic data, the drilling parameter is further introduced as a constraint and there is a low-frequency correlation between the drilling parameter and the logging parameter, which has a significant improvement effect, especially in terms of low-frequency components of the prediction result. Therefore, by integrating the low-frequency information, it is still possible to predict the parameters within a certain range of the strata ahead, even in the areas with a small number of adjacent wells and scanty logging data, and the velocity model can be dynamically adjusted, thereby significantly improving the accuracy of the velocity model. The present application achieves the comprehensive utilization of the drilling parameter, the logging parameter and the seismic data and gives full play to the advantages of various data, thereby providing abundant information sources for the construction and optimization of the first velocity model, and improving the overall accuracy of the velocity model.

### BRIEF DESCRIPTION OF THE DRAWINGS

In order to illustrate the technical solutions in the embodiments of the present application or in the prior art more clearly, a brief description will be given to the accompanying drawings required for the description of the embodiments or the prior art. Obviously, the accompanying drawings in the following description are merely intended for some embodiments of the present application, and for those ordinary skilled in the art, other drawings can also be obtained from these drawings without creative efforts.

FIG. 1 is a first schematic flowchart of a model training method according to an embodiment of the present application.

FIG. 2 is a comparison diagram and a probability distribution diagram of well data before and after pre-processing according to an embodiment of the present application.

FIG. 3 is a second schematic flowchart of a model training method according to an embodiment of the present application.

FIG. 4 is a schematic matrix diagram of a correlation between a longitudinal wave velocity and a plurality of drilling parameters according to an embodiment of the present application.

FIG. 5 is a schematic diagram of establishing a model based on an intelligent time-series network according to an embodiment of the present application.

FIG. 6 is a schematic diagram of changes in drilled, training, and predictive parts of a drilling well during a gradual drilling process according to an embodiment of the present application.

FIG. 7 is a schematic diagram of an original velocity model in a non-drilling stage according to an embodiment of the present application.

FIG. 8 is a schematic diagram of an original velocity model after being optimized by seismic data in a non-drilling stage according to an embodiment of the present application.

FIG. 9 is a schematic diagram of an original velocity model in a first stage of drilling according to an embodiment of the present application.

FIG. 10 is a schematic diagram of an original velocity model after being optimized by seismic data in a first stage of drilling according to an embodiment of the present application.

FIG. 11 is a schematic diagram of an original velocity model in a second stage of drilling according to an embodiment of the present application.

FIG. 12 is a schematic diagram of an original velocity model after being optimized by seismic data in a second stage of drilling according to an embodiment of the present application.

FIG. 13 is a schematic diagram of an original velocity model in a third stage of drilling according to an embodiment of the present application.

FIG. 14 is a schematic diagram of an original velocity model after being optimized by seismic data in a third stage of drilling according to an embodiment of the present application.

FIG. 15 is a schematic structural diagram of a model training apparatus according to an embodiment of the present application.

FIG. 16 is a schematic structural diagram of an electronic device according to an embodiment of the present application.

### DESCRIPTION OF EMBODIMENTS

In embodiments of the present application, terms such as “first” and “second” are used to distinguish the same or similar items whose functions and effects are basically the same. Those skilled in the art should understand that the terms such as “first” and “second” do not limit the quantity and execution order, and also do not necessarily imply differences. It should be noted that, in embodiments of the present application, terms such as “exemplary” or “for example” are used to denote examples, illustrations, or explanations. Any embodiments or design schemes described as “exemplary” or “for example” in this application should not be interpreted as being more preferred or advantageous over other embodiments or design schemes. Specifically, the terms such as “exemplary” or “for example” are used to present related concepts in a concrete manner. In embodiments of the present application, “at least one” refers to one or more, and “a plurality of” refers to two or more.

It should be noted that, in embodiments of the present application, “at the time of . . . ” may refer to a moment when a certain condition occurs, and may also be within a period of time after a certain condition occurs, which is not specifically limited in the embodiments of the present application. In addition, the model training method provided in embodiments of the present application is merely an example, and the model training method may also include more or fewer content.

In order to describe the technical solution of embodiments of the present application clearly, some terms and technologies involved in the embodiments of the present application are briefly introduced in the below.

Drilling parameter: the drilling parameter refers to various physical and engineering parameters that are used to describe and control drilling operations during a drilling progress. These parameters include type and specification of a drill bit, properties and composition of drilling fluid, drilling speed and rotational speed, and drilling pressure control parameters, etc. The present application utilizes the drilling parameter acquired in real time to obtain a corresponding predictive logging parameter, and performs a synchronous prediction of velocity parameters based on the predictive logging parameter. Such an ahead-of-bit prediction enables effective velocity prediction in the absence of actual logging data, thereby providing a reference prediction result for the strata ahead.

Logging parameter: the logging parameter refer to physical properties and structural information of the strata obtained by real-time or intermittent measurements of the strata inside a well through logging tools. Such information includes resistivity measurements (electrical logging), natural gamma radiation measurements, acoustic wave measurements (acoustic logging), and nuclear magnetic resonance measurements.

Seismic data: in the field of drilling, the seismic data mainly refers to data obtained by detecting underground geological structures through seismic waves, which helps identify the type, the thickness and the structure of the underground rock strata by analyzing the propagation speeds and reflection characteristics of the seismic waves in different rock strata. The seismic data mainly focuses on the heterogeneous characteristics of the strata, and the introduction of the seismic data provides more abundant geological information for drilling prediction, especially with the support of amplitude information, which can provide a more detailed description of the changes in the strata, thereby improving the prediction accuracy. The present application utilizes seismic data to optimize the constructed velocity model, so as to improve the prediction accuracy of the velocity model in areas with strong heterogeneity of underground media.

The exemplary embodiments will be described in detail herein, and the examples thereof are illustrated in the accompanying drawings. When referring to the accompanying drawings in the following description, unless otherwise indicated, the same numbers in different drawings represent the same or similar elements. The implementations described in the following exemplary embodiments do not represent all implementations consistent with the present application. On the contrary, they are merely examples of apparatuses and methods that are consistent with some aspects of the present application as detailed in the appended claims.

The following provides a detailed explanation of the technical solution of the present application through the specific embodiments. The following specific embodiments may be combined with each other, and the same or similar concepts or processes may not be repeated in some embodiments. Hereinafter, the embodiments of the present application will be described with reference to the accompanying drawings.

To clearly understand the technical solution of the present application, the solution in the prior art is first described in detail.

At present, a model construction manner in which logging data and seismic horizon data are combined is mainly adopted in the construction of the velocity model. Such approach of constructing the velocity model according to existing logging data and seismic horizon data is simple and easy to use, but it is difficult in this approach to fully capture geological changes near wells to be drilled in areas with strong heterogeneity of underground media and a small number of adjacent wells and scanty logging data, resulting in low prediction accuracy.

Therefore, with regard to the problem of low accuracy due to data scarcity in using the velocity model constructed in the prior art for the areas with strong heterogeneity of underground media and a small number of adjacent wells, and scanty logging data, it was found in the research that in order to solve this problem, \textcircled{1} a drilling parameter of an explored well, a logging parameter of the explored well, and a drilling parameter of a target drilling well are first pre-processed: the data pre-processing operations involved include removing outliers and data smoothing filtering, etc., so as to improve the quality and the reliability of multi-source data and lay a foundation for subsequent analysis and model construction; \textcircled{2} a first velocity model is constructed according to the pre-processed logging parameter of the explored well: the first velocity model around the drilling well is constructed by combining the known acoustic wave velocity logging information of the explored well. The first velocity model does not incorporate seismic amplitude, waveform information and real-time drilling parameters, and mainly relies on low-frequency logging information and the seismic horizon data of the explored well to reflect macroscopic characteristics of the strata; \textcircled{3} a predictive drilling parameter is obtained according to the pre-processed drilling parameter of the target drilling well and the pre-processed drilling parameter of the explored well; \textcircled{4} the first velocity model is optimized by introducing seismic data of the explored well and the target drilling well and the predictive drilling parameter as constraints.

Specifically:
pre-process a drilling parameter of an explored well, a logging parameter of the explored well, and a drilling parameter of a target drilling well, where the pre-processing includes data outlier processing and data smoothing filtering;
construct a first velocity model according to the pre-processed logging parameter of the explored well;
obtain a predictive drilling parameter according to the pre-processed drilling parameter of the target drilling well and the pre-processed drilling parameter of the explored well; and
perform a first-level iterative optimization on the first velocity model according to the predictive drilling parameter and seismic data of the explored well and the target drilling well.

In the model training method in the embodiments of the present application, the first velocity model is constructed based on the principle of preset working conditions mentioned above, and then the first velocity model is continuously and iteratively optimized according to the pre-processed seismic data of the explored well and the target drilling well, as well as the drilling parameters of the explored well and the target drilling well. By combining the pre-processed seismic data of the explored well and the target drilling well, as well as the drilling parameters of the explored well and the target drilling well, the accuracy of the constructed first velocity model can be improved in areas with strong heterogeneity of underground media and a small number of adjacent wells, and scanty logging data.

Based on the described inventive findings, the technical solution of the present application is proposed.

The application scenarios of the model training method provided in the embodiments of the present application will be introduced in the below.

Constructing the first velocity model through the model training method in this solution and optimizing the first velocity model based on the seismic data and the drilling parameters of the explored well and the target drilling well may be applied to: predicting the pressure, the temperature and the rock properties of the strata by constructing the velocity model, which helps researchers select suitable drill bit types, drilling speeds and mud parameters in order to improve the drilling efficiency; using the velocity model to monitor the drilling parameter in real time during a drilling process and adjusting operational strategies in time, so as to reduce the occurrence of faults and accidents; analyzing the changes in formation pressure and porosity through the velocity model to determine the stability of the wellbore so as to avoid wellbore instability.

The embodiments of the present application will be introduced in conjunction with the accompanying drawings in the below.

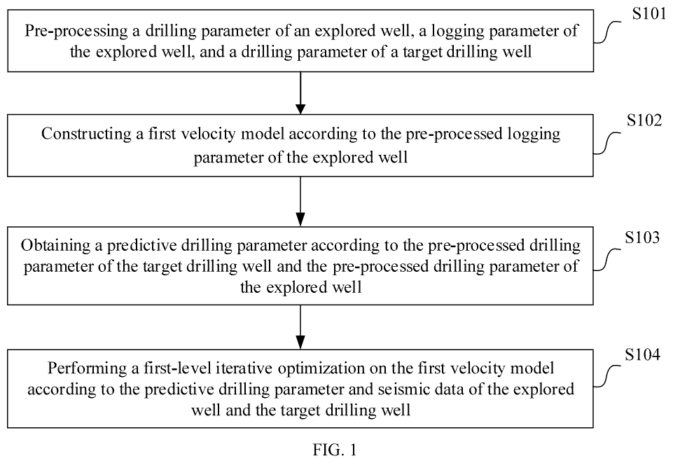

FIG. 1 is a first schematic flowchart of a model training method according to an embodiment of the present application, and the model training method provided in this embodiment includes the following steps S101-S104.

S101, pre-processing a drilling parameter of an explored well, a logging parameter of the explored well, and a drilling parameter of a target drilling well.

In this embodiment, the pre-processing includes data outlier processing and data smoothing filtering, and the target drilling well is a well which is being drilled.

The data sources for the pre-processing include three-dimensional seismic data of a work zone, seismic horizon data, existing well exploration data (logging, drilling, and recording, etc.) and well positions and well trajectories of the wells to be drilled in the work zone. The pre-processing is mainly responsible for preliminarily processing the collected drilling parameter and logging parameter so as to improve the data quality and the reliability of the inversion result. Specifically, the drilling parameter of the explored well, the logging parameter of the explored well, and the drilling parameter of the target drilling well are pre-processed.

Specifically, the seismic data is processed into high-quality stacked seismic data by seismic data processing personnel, and the processing of target drilling data mainly includes data outlier processing and data smoothing filtering, so as to improve the quality and the reliability of the multi-source data. The stability and the accuracy of the input data are ensured by strictly processing the outliers and smoothing the signal, thereby laying the foundation for subsequent analysis and the construction of the velocity model.

The purpose of the data outlier processing is to detect and process the outliers in the target drilling parameter, and especially to remove errors introduced by operation errors or instrument noise. The data outlier processing may be carried out by using conventional methods such as the 3σ rule or the box plot method for data cleaning, and these methods can effectively identify and eliminate data points that deviate from the normal range, thereby improving the overall quality of data. The purpose of the data smoothing filtering is to remove high-frequency noise in the target drilling parameter, and to retain low-frequency components reflecting the macroscopic characteristics of the strata. The low-frequency components are crucial for the construction of the velocity model and the prediction, and can effectively capture the main trends and structures of the strata, thereby improving the smoothness and the stability of the data. For the specific methods of data smoothing filtering, conventional filtering techniques such as a sliding average method or a low-pass filter may be used. By efficiently pre-processing the data, a firm foundation can be provided for the subsequent analysis and the construction of the velocity model, and a reliable data support can be established for real-time adjustment and optimization of the model during the drilling process.

S102, constructing a first velocity model according to the pre-processed logging parameter of the explored well.

In this embodiment, a first velocity model, i.e. an original velocity model, is constructed around the drilling well based on the three-dimensional seismic horizon data in combination with the known acoustic wave velocity logging parameter information of the explored well. The first velocity model does not incorporate the seismic amplitude, the waveform information and the real-time drilling parameters, and mainly relies on the low-frequency logging parameter information and the seismic horizon data of the explored well to reflect the macroscopic characteristics of the strata.

S103, obtaining a predictive drilling parameter according to the pre-processed drilling parameter of the target drilling well and the pre-processed drilling parameter of the explored well.

In this embodiment, the drilling parameters for the future drilling depth are gradually predicted by combining the drilling parameter of the target drilling well and the historical drilling parameter of the explored well, and this process is referred to as ahead-of-bit prediction. The introduction of real-time drilling parameters optimizes the low-frequency information in the velocity model, and the ahead-of-bit prediction enables the velocity prediction to be effectively performed in the absence of actual logging data, so as to provide a reference prediction result for the strata ahead, thereby significantly improving the accuracy of the velocity model.

S104, performing a first-level iterative optimization on the first velocity model according to the predictive drilling parameter and seismic data of the explored well and the target drilling well.

In this embodiment, compared with the method of constructing the velocity model based on the logging parameter and the seismic horizon data, the velocity prediction guided by the seismic data optimizes and adjusts the velocity model by supplementing the amplitude information, structure information and waveform information of the seismic data, thereby improving the accuracy and the reliability of the model, and solving the influence of the heterogeneity strength of the underground media to a certain extent.

An objective function of a model-driven inversion method is mainly composed of a data fidelity term and a regularization constraint term. The data fidelity term ensures the similarity between synthetic seismic data and actual seismic data, while the regularization constraint term is configured to control the stability of the model and avoid over-fitting. The objective function may be expressed as:

$$J ( z ) = {‖ d - Gz ‖}^{2} + λ∅ ( {Z}_{initial} )$$

where, Gz is synthetic seismic data, G is a forward operator, z is the velocity model to be inverted, dis actual seismic data, and λ is a regularization parameter for balancing weights of the data fidelity term and the regularization constraint term.

The first term is the data fidelity term, which ensures that the synthesized seismic data Gz is close to the actual seismic data d through a least squares method; and the second term is the regularization constraint term, which utilizes the velocity model Zᵢₙᵢₜᵢₐₗ to improve the robustness of inversion and reduce non-uniqueness.

$${‖ d - Gz ‖}^{2} = {\sum }_{i = 1}^{n} {( {d}_{i} - {Gz}_{i} )}^{2}$$

where, dᵢ is an i-th sampling point of the actual seismic data, Gzᵢ is an i-th sampling point of the synthetic seismic data, and an optimal velocity model z can be obtained by optimizing the objective function J(z), and for the optimization process, usually a gradient descent method or other numerical optimization algorithms are utilized for iteration.

The amplitude information in the seismic data plays a vital role in this process, and can capture and correct the reflection characteristics of the strata so as to make an elastic parameter of the inversion result consistent with the actual seismic amplitude data. In addition, the introduction of the structural information and the waveform information can help accurately position the spatial distribution and the geological structure of the strata, so as to ensure that the inversion result not only matches the actual geological morphology, but also accurately reproduces propagation paths and time-to-arrival characteristics of the seismic waves. Compared with simple well and horizon extrapolation interpolation methods, the model-driven inversion combines more abundant seismic data, which can not only reflect macroscopic structures of the strata, but also reveals subtle geological features.

After a wave impedance is obtained, the specific conversion relationship between the impedance and the velocity as well as the density can be obtained by cross plot analysis of the velocity and the density in the logging parameter of the explored well, and the wave impedance data can be accurately converted into a velocity prediction result in stratified segments, that is, a seismic-guided velocity prediction result Vₛₑᵢ.

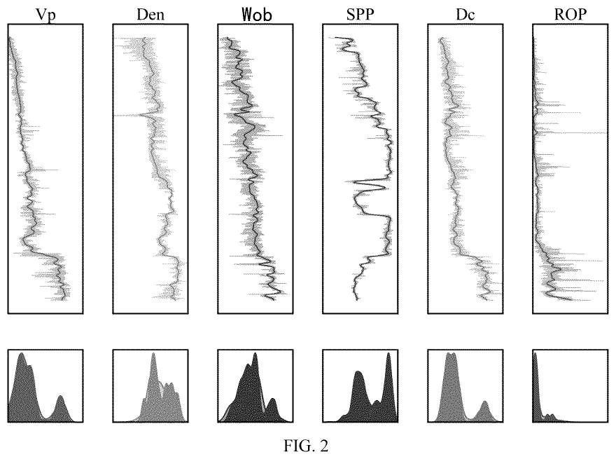

FIG. 2 is a comparison diagram and a probability distribution diagram of well data before and after pre-processing according to an embodiment of the present application, mainly including curves that the logging data such as longitudinal wave velocity (Vp) and density (Den), and the drilling parameters such as weight-on-bit (Wob), standpipe pressure (SPP), Dc index, and rate of penetration (ROP) that vary with the depth and corresponding probability density distributions thereof. During the pre-processing process, the outliers and noise in the data are cleared, and the high-frequency interference is eliminated through a low-pass filtering method. It can be seen that there is a significant improvement in the sequence data visualization of the data after pre-processing, and in particular, the abnormal data is effectively processed, resulting in a smoother trend. At the same time, despite being processed, the data remain unchanged in its overall distribution characteristics, and the distribution curves remain close, thereby ensuring that the authenticity of the original data is preserved.

The present application provides a model training method and an apparatus, and the model training method includes: pre-processing the drilling parameter of the explored well, the logging parameter of the explored well, and the drilling parameter of the target drilling well; constructing the first velocity model according to the pre-processed logging parameter of the explored well; obtaining the predictive drilling parameter according to the pre-processed drilling parameter of the target drilling well and the pre-processed drilling parameter of the explored well; and performing the first-level iterative optimization on the first velocity model according to the predictive drilling parameter and the seismic data of the explored well and the target drilling well. According to the above-described method, the following technical effects have been achieved: on the basis of constructing the first velocity model, the seismic data is added, and the seismic data mainly focuses on the heterogeneous characteristics of the strata during this process, and the changes in the strata can be described more finely through the introduction of the seismic data, especially with the support of amplitude information. Therefore, by using the seismic data to modify and optimize the first velocity model, the prediction accuracy of the velocity model in the areas with strong heterogeneity of the underground media can be improved. On the basis of the seismic data, the drilling parameter is further introduced as a constraint and there is a low-frequency correlation between the drilling parameter and the logging parameter, which has a significant improvement effect, especially in terms of low-frequency components of the prediction result. Therefore, by integrating the low-frequency information, it is still possible to predict the parameters within a certain range of the strata ahead, even in the areas with a small number of adjacent wells and scanty logging data, and the velocity model can be dynamically adjusted, thereby significantly improving the accuracy of the velocity model. The present application achieves the comprehensive utilization of the drilling parameter, the logging parameter and the seismic data and gives full play to the advantages of various data, thereby providing abundant information sources for the construction and optimization of the first velocity model, and improving the overall accuracy of the velocity model.

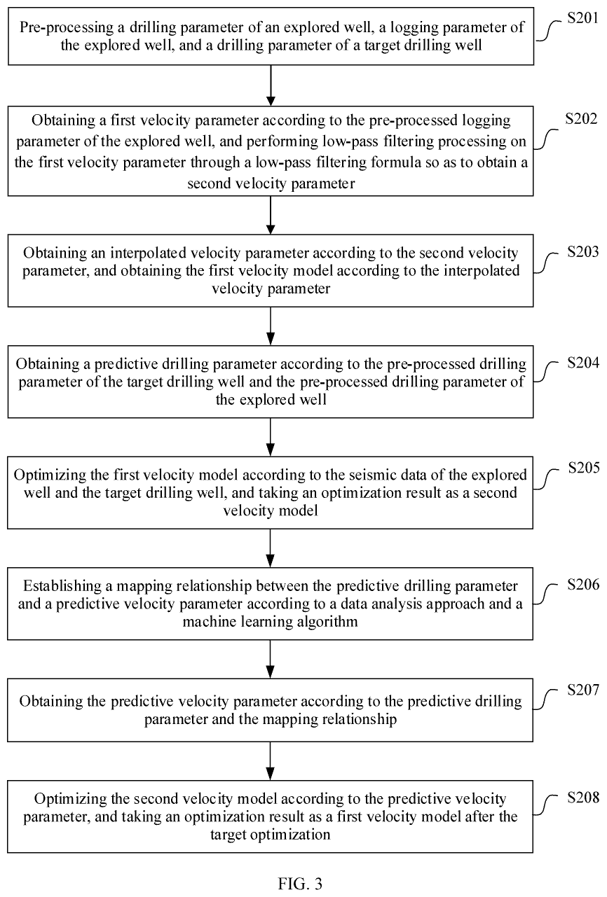

FIG. 3 is a second schematic flowchart of a model training method according to an embodiment of the present application. As shown in FIG. 3, the model training method provided in this embodiment is a further refinement based on the model training method provided in the previous embodiment of the present application. The model training method provided in this embodiment includes the following steps S201-S208.

S201, pre-processing a drilling parameter of an explored well, a logging parameter of the explored well, and a drilling parameter of a target drilling well.

In this embodiment, the pre-processing includes data outlier processing and data smoothing filtering.

The implementation and the effect of S201 are similar to those of S101 in the previous embodiment of the present application, and thus will not be repeated herein.

S202, obtaining a first velocity parameter according to the pre-processed logging parameter of the explored well, and performing low-pass filtering processing on the first velocity parameter through a low-pass filtering formula so as to obtain a second velocity parameter, where the low-pass filtering formula is:

$${V}_{low} ( f ) = \{ \begin{matrix}V ( f ) , & if \vert f \vert \leq {f}_{c} \\ 0 , & if \vert f \vert > {f}_{c}\end{matrix}$$

where, V_{low}(f) is the second velocity parameter (i.e. the velocity parameter after the low-pass filtering processing), V(f) is the first velocity parameter (i.e. the velocity parameter without low-pass filtering processing), and f_{c} is a cut-off frequency.

In this embodiment, the low-frequency information can reflect the macroscopic characteristics and overall structure of the strata, while the high-frequency information usually contains noise and local irregularities, and these high frequency components are easily affected by geological abnormalities, logging instrument noise or human operation errors, which may lead to the accumulation of errors in the velocity model. The low-frequency information plays a control role in constructing the first velocity model, and can provide critical control points for the first velocity model, thereby ensuring that the low-frequency components of the first velocity model accurately reflect the basic characteristics of the strata.

In this embodiment, before obtaining the corresponding velocity curve according to the pre-processed logging parameter of the explored well, and performing the low-pass filtering processing on the velocity curve through the low-pass filtering formula so as to obtain the second velocity parameter, the method further includes: synthesizing seismic records by using the logging data of the explored well. The purpose of synthesizing the seismic records is to generate the seismic data through the logging parameter, so as to correct and verify the actual seismic data, thereby ensuring the accuracy of a time-depth relationship. A stratigraphic horizon model is constructed according to the construction and interpretation result of the seismic data obtained from the seismic records, and stratigraphic interfaces and structural features are defined with reference to the geometric characteristics of the geological structures, so as to more accurately comply with geomorphic features. The low-pass filtering processing is performed on the velocity curve, so as to extract the second velocity parameter of the velocity curve, and the second velocity parameter herein belongs to the low-frequency information.

S203, obtaining an interpolated velocity parameter according to the second velocity parameter, and obtaining the first velocity model according to the interpolated velocity parameter.

In this embodiment, the detailed stratigraphic horizon model and the velocity curve with control points are combined to interpolate in three-dimensional space to obtain the first velocity model.

In an implementation, in this embodiment, the interpolated velocity parameter is obtained through an interpolation formula (in this embodiment, a Kriging interpolation formula is used as an example) according to the second velocity parameter; and the interpolation formula is:

$$V ( x , y , z ) = {\sum }_{j = 1}^{n} {λ}_{j} {V}_{j}$$

where, V(x, y, z) is the interpolated velocity parameter, n is an amount of control points, Vⱼ is the second velocity parameter, λⱼ is an interpolation weight obtained through a weight formula; and the weight formula is:

$$\{ \begin{matrix}{\sum }_{j = 1}^{n} {λ}_{j} γ ( {d}_{ij} ) + μ = γ ( {d}_{i 0} ) \\ {\sum }_{j = 1}^{n} {λ}_{j} = 1\end{matrix}$$

where, γ(dᵢⱼ) is a semi-variogram of spatial correlation between the control points in a velocity parameter curve, γ(dᵢ₀) is a semi-variogram of spatial correlation between the control points and points to be interpolated in the velocity parameter curve, μ is a Lagrange number, and n is the amount of the control points.

S204, obtaining a predictive drilling parameter according to the pre-processed drilling parameter of the target drilling well and the pre-processed drilling parameter of the explored well.

In an implementation, in this embodiment, the predictive drilling parameter is obtained through an ahead-of-bit prediction formula indicated by a time-series forecasting model according to pre-processed drilling parameters at a plurality of time points of the target drilling well, and the pre-processed drilling parameter of the explored well; and the ahead-of-bit prediction formula is:

$${P}_{t + h} = F ( {P}_{t} , {P}_{t - 1} , … , {P}_{t - n} , H )$$

where, Pₜ₊ₕ is the predictive drilling parameter, F( ) is the time-series forecasting model, Pₜ is a pre-processed drilling parameter of the target drilling well at a current time point, Pₜ₋₁ is a pre-processed drilling parameter of the target drilling well at a time point relative to which the current time point has passed one time point, Pₜ₋ₙ is a pre-processed drilling parameter of the target drilling well at a time point relative to which the current time point has passed n time points, and H is the pre-processed drilling parameter of the explored well.

In the prediction process, the real-time data can be continuously newly added as the drilling progresses, so that the drilling parameter of the strata ahead of the drill bit is gradually predicted forward, and the formula is:

$${P}_{t + h + 1} = F ( {P}_{t + 1} , {P}_{t} , … {P}_{t - n + 1} , H )$$

where, Pₜ₊ₕ₊₁ is the predictive drilling parameter, F( ) is the time-series forecasting model, Pₜ₊₁ is the pre-processed drilling parameter of the target drilling well at a current time point, Pₜ is the pre-processed drilling parameter of the target drilling well at a time point relative to which the current time point has passed one time point, Pₜ₋ₙ₊₁ is the pre-processed drilling parameter of the target drilling well at a time point relative to which the current time point has passed n time points, and H is the pre-processed drilling parameter of the explored well.

S205, optimizing the first velocity model according to the seismic data of the explored well and the target drilling well, and taking an optimization result as a second velocity model.

In this embodiment, the seismic data is added on the basis of constructing the first velocity model, and the first velocity model is corrected and optimized through a guiding effect of the seismic data, and this process can more accurately capture subtle changes in the strata, thereby further enhancing the accuracy of the first velocity model.

In an implementation, in this embodiment, the second velocity model is obtained through a first velocity model update formula according to the seismic data and the first velocity model; and the first velocity model update formula is:

$${V}_{1} = seismic ( V )$$

where, V₁ is the second velocity model, V is the first velocity model, and seismic is an update process of the first velocity model.

S206, establishing a mapping relationship between the predictive drilling parameter and a predictive velocity parameter according to a data analysis approach and a machine learning algorithm.

In this embodiment, after the data pre-processing is completed, the drilling parameters (e.g., weight-on-bit, rotational speed, Dc index, and mud density, etc.) of the explored well are analyzed in depth, so as to explore the correlation between them and critical parameters such as seismic speed and density. By using methods such as a data crossplot, a correlation calculation and a principal component analysis, combined with the machine learning algorithms (e.g., depth learning, regression analysis, etc.), the critical logging parameters such as velocity can be calculated from the known drilling parameters, and the mapping relationship between the drilling parameters and the velocity parameters is established. This step provides a critical support for the optimization of dynamic velocity prediction with drilling.

The data correlation analysis aims to analyze the correlation between the drilling parameters and the logging parameters such as seismic velocity and density, and to extract useful features for constructing the velocity model. By means of the data correlation analysis, the critical drilling parameters that can reflect underground medium information can be identified, and these drilling parameters can be used to obtain a predictive target logging parameter.

The drilling parameters of the explored well are analyzed, and the distribution characteristics (such as mean, variance, maximum, minimum, etc.) and physical meaning of each parameter are determined. For example, the weight-on-bit (Wob) reflects the pressure exerted by the drill bit on the strata. A higher weight-on-bit generally indicates that the drill bit is drilling into hard strata, while a lower weight-on-bit may indicate that the drill bit is working in soft strata. The rotational speed (Rpm) affects the wearing and the rate of penetration of the drill bit, and a higher rotational speed may be typically indicative of the hard strata, and a lower rotational speed may be indicative of the soft strata. The mud weight (Mw) is used to balance the formation pressure so as to prevent blowouts and well collapses.

In particular, the Dc index, as an important index for evaluating the drilling difficulty of the strata and the efficiency of the drill bit, is generally closely related to physical properties of rocks such as hardness and density. Harder rocks generally have a higher density and result in a faster seismic wave propagation velocity, leading to a higher Dc index, while softer rocks exhibit a lower Dc index. By analyzing the correlation of the Dc index with the velocity parameter, an important reference can be provided for the construction of the velocity model.

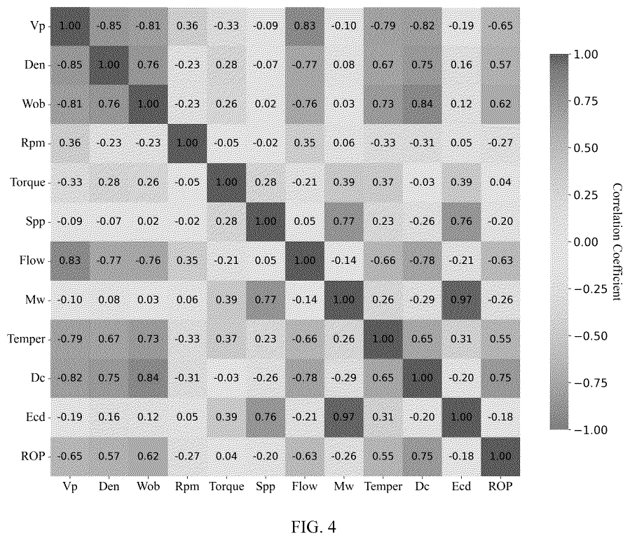

FIG. 4 is a schematic matrix diagram of a correlation between a longitudinal wave velocity and a plurality of drilling parameters according to an embodiment of the present application. The figure illustrates the correlation between the longitudinal wave velocity (Vp) and the plurality of drilling parameters, and reveals the degree of influence of each parameter on the formation velocity. The numerical values in the matrix represent the correlation coefficients between different parameters, and the depth of color reflects the strength of the correlation. Among them, Wob stands for the weight-on-bit, Rpm stands for the rotational speed, Torque stands for the torque, Spp stands for the standpipe pressure, Flow stands for the drilling fluid flow rate, Mw stands for the drilling fluid density, Temper stands for the temperature, Dc stands for the DC index, Ecd stands for the equivalent circulating density, and ROP stands for rate of penetration. The correlation coefficient between the Dc index and the longitudinal wave velocity is the highest, i.e., 0.91, indicating that the Dc index may play an important role in predicting the longitudinal wave velocity.

In the process of the data analysis, it is very crucial to select appropriate analysis methods, and the common methods include data crossplot analysis, correlation calculation and principal component analysis, etc. Through the data crossplot analysis, a relationship between the drilling parameter and the velocity parameter can be visually displayed. The correlation calculation can quantify a correlation coefficient between each drilling parameter and the velocity parameter, so as to determine which parameters are closely related to the velocity parameter. The principal component analysis can extract the most important feature parameter through a dimensionality reduction technique, thereby simplifying the model complexity, and improving the accuracy and efficiency of the prediction. For example, for the correlation analysis between the Dc index and the velocity parameter, a correlation coefficient formula is used:

$$ρ = \frac{Cov ( Dc , V )}{{σ}_{Dc} {σ}_{V}}$$

where, ρ is the correlation coefficient between the DC index and the velocity parameter, Cov(Dc, V) is a covariance, and σ is a standard deviation.

S207, obtaining the predictive velocity parameter according to the predictive drilling parameter and the mapping relationship.

After the predictive drilling parameter is obtained, the relationship between the predictive drilling parameter and the predictive velocity parameter is determined through the correlation analysis results of the explored well data. By using an artificial intelligence learning method, especially a time-series prediction method in depth learning, a non-linear relationship between the drilling parameter and the velocity parameter can be fitted, and an accurate mapping model is formed by training with a large amount of historical data. During an actual drilling process, the drilling parameter of the explored well is acquired in real time, and is input into a trained intelligent model, so as to predict the corresponding velocity parameter in real time.

In this embodiment, during the actual drilling process, the drilling parameter of the target drilling well is acquired in real time, and is input into the trained time-series intelligent model, so as to obtain a corresponding predictive velocity parameter. The prediction formula is as follows:

$${V}_{pred} = F ( Wob , Rpm , Mw , Rop … )$$

Here, for the training and prediction parameters, the weight-on-bit (Wob), the rotational speed (Rpm), the mud weight (Mw), and the rate of penetration (Rop) in the predictive drilling parameter are mainly taken as examples.

In an implementation, in this embodiment, the predictive velocity parameter corresponding to the drilling parameter is obtained through a prediction formula indicated by the mapping relationship; and the prediction formula is:

$${V}_{pred} = F ( {P}_{t + h} )$$

where, V_{pred} is the predictive velocity parameter, F( ) is a trained time-series intelligent model, and Pₜ₊ₕ is the predictive drilling parameter.

By the predictive velocity parameter, it can be further applied to the optimization process of the velocity model, thereby enabling dynamic updating and optimization of the geological model.

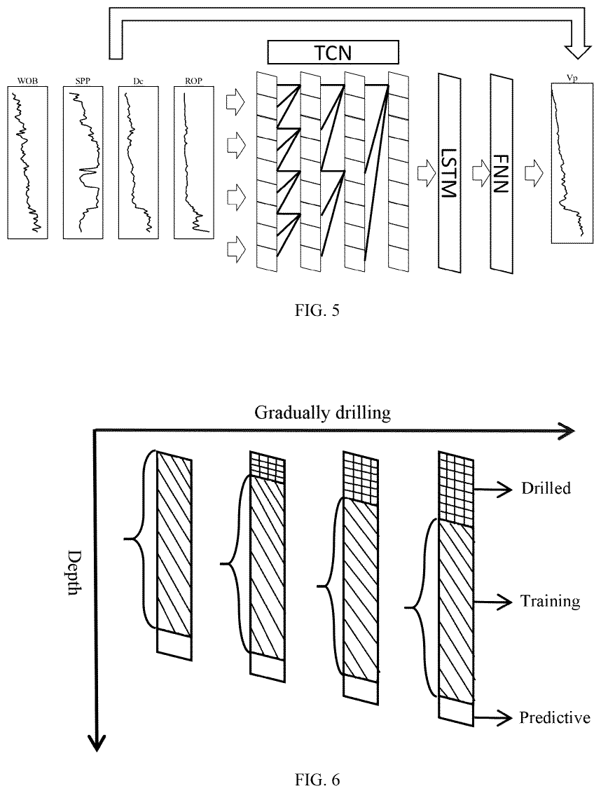

FIG. 5 is a schematic diagram of establishing a model based on an intelligent time-series network according to an embodiment of the present application. For the construction of the “drilling parameter-velocity parameter” model based on the intelligent time-series network, the input drilling parameters (including various drilling parameters such as Ecd, Dc, Flow, Mw, Torque, etc.) are firstly processed through a temporal convolutional network (Temporal Convolutional Network, TCN) for feature extraction, the time-series features are then processed through a long short-term memory (Long Short-Term Memory, LSTM), and finally, a fully connected neural network (Fully Connected Neural Network, FNN) is used for regression analysis to output the corresponding velocity parameters. Such intelligent time-series network architecture may effectively capture a complex non-linear relationship between the drilling parameter and the velocity parameter, thereby realizing accurate prediction and matching. FIG. 6 is a schematic diagram of changes in drilled, training, and predictive parts of a drilling well during a gradual drilling process according to an embodiment of the present application.

S208, optimizing the second velocity model according to the predictive velocity parameter, and taking an optimization result as a first velocity model after a target optimization.

In an implementation, in this embodiment, an optimized second velocity model is obtained through a second velocity model update formula according to the predictive velocity parameter and the second velocity model; and the second velocity model update formula is:

$${V}_{2} = initial ( {V}_{1} , {V}_{pred} )$$

where, V₂ is the optimized second velocity model, V₁ is the second velocity model, V_{pred} is the predictive velocity parameter, and initial is an update process of the second velocity model.

The second velocity model is optimized by introducing the predictive velocity parameter, and the velocity distribution of the second velocity model is gradually updated, so that the second velocity model can be made closer to an actual geological situation.

In particular, within a specific range around the drilling well, the emphasis is placed on optimizing and updating the model in a focused manner, so as to ensure the prediction accuracy of the model in critical areas. The velocity model is continuously updated by continuously acquiring and applying the real-time drilling parameter and combining it with the seismic data. The iterative optimization process enables the model to reflect new information acquired during the drilling process in time, so that the model gradually approaches the actual geological condition, thereby reducing prediction errors.

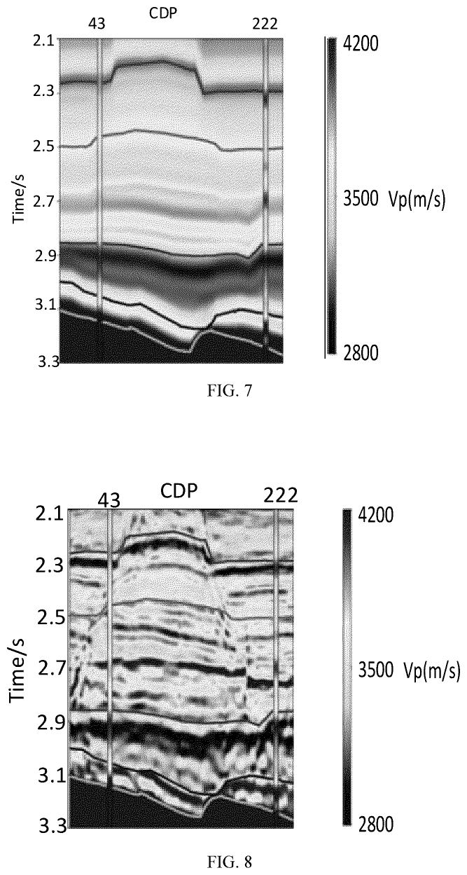

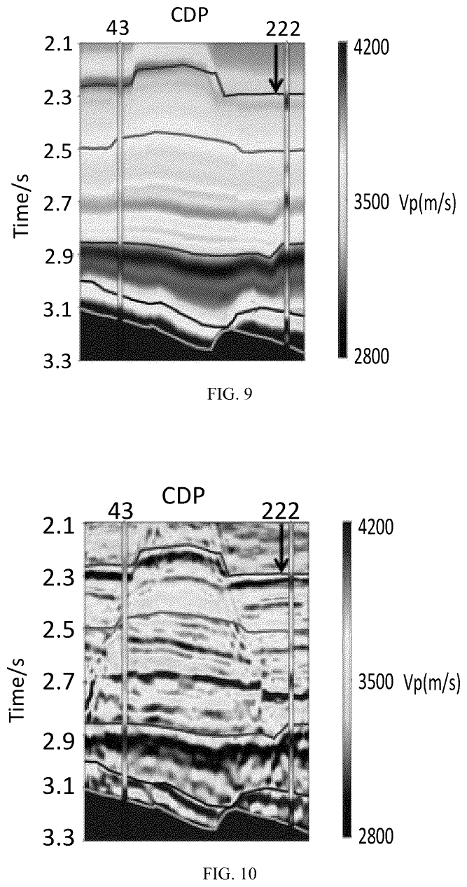

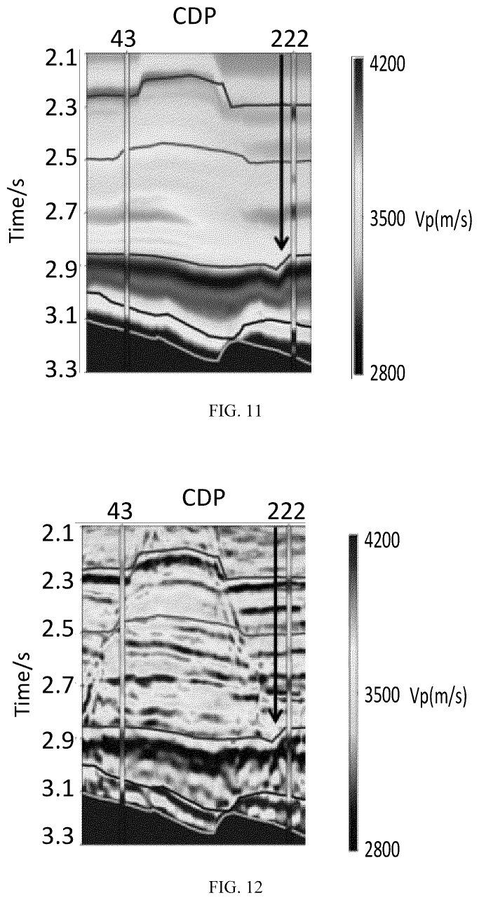

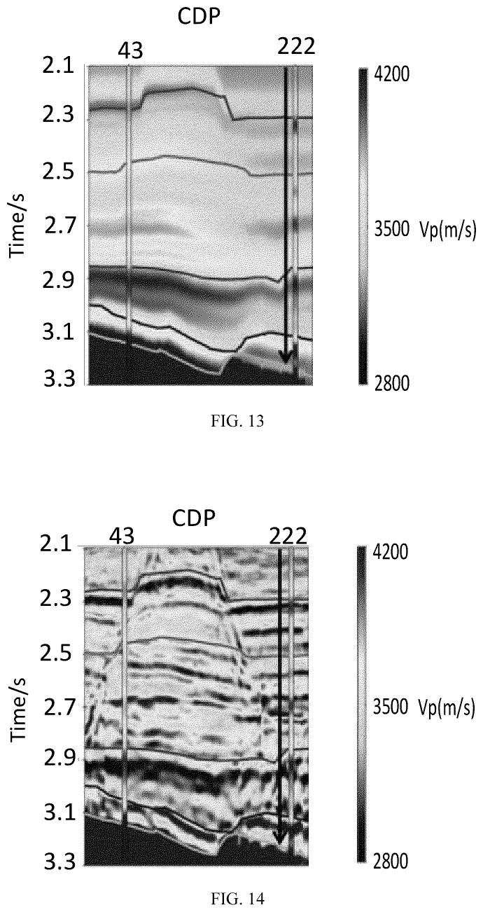

FIG. 7 is a schematic diagram of an original velocity model in a non-drilling stage according to an embodiment of the present application, FIG. 8 is a schematic diagram of an original velocity model after being optimized by seismic data in a non-drilling stage according to an embodiment of the present application, FIG. 9 is a schematic diagram of an original velocity model in a first stage of drilling according to an embodiment of the present application, FIG. 10 is a schematic diagram of an original velocity model after being optimized by seismic data in a first stage of drilling according to an embodiment of the present application, FIG. 11 is a schematic diagram of an original velocity model in a second stage of drilling according to an embodiment of the present application, FIG. 12 is a schematic diagram of an original velocity model after being optimized by seismic data in a second stage of drilling according to an embodiment of the present application, FIG. 13 is a schematic diagram of an original velocity model in a third stage of drilling according to an embodiment of the present application, and FIG. 14 is a schematic diagram of an original velocity model after being optimized by seismic data in a third stage of drilling according to an embodiment of the present application.

When a validation well has not yet been drilled, the low-frequency velocity model mainly relies on the interpolation of the velocities from the adjacent wells, resulting in certain errors in zones with complex structures. In FIG. 7, the differences between the validation well projection and the nearby migration results around the wellbore can be seen: 1) the depth of the low-velocity zones at 2.3 s in FIG. 7 is misaligned; 2) in FIG. 7, the low-velocity zones at 2.7 s is overestimated, and parts of the strata, which should have manifested as the low-velocity zones, show higher velocities; 3) the position of the low-velocity layer near 3.0 s in FIG. 7 is too deep. The wellbore-seismic fusion speed prediction result in the non-drilling stage (FIG. 8) captures more details in the high-frequency part, but its reflection of the stratigraphic horizon is still not accurate enough. As drilling proceeds, from stage 1 to stage 3 (FIGS. 9-14), the low-frequency model is gradually updated by combining the drilling data and the seismic information, especially in the critical zones at 2.3 s and 2.7 s, where the misalignment of low-velocity values is corrected, and the characteristics of the high-velocity and low-velocity zones appear gradually, which is more consistent with the actual geological structure. At stage 4, the adjustment effect of the model in the zones at 3.0 s of the deep horizon is significant.

The technical effects of the present embodiment are as follows: the seismic data is added on the basis of constructing the first velocity model, the seismic data mainly focuses on the heterogeneous characteristics of the strata during this process, and the changes in the strata can be described more finely through the introduction of the seismic data, especially with the support of amplitude information. Therefore, by using the seismic data to modify and optimize the first velocity model, the prediction accuracy of the velocity model in the areas with strong heterogeneity of the underground media can be improved. On the basis of the seismic data, the drilling parameter is further introduced as a constraint and there is a low-frequency correlation between the drilling parameter and the logging parameter, which has a significant improvement effect, especially in terms of low-frequency components of the prediction result. Therefore, by integrating the low-frequency information, it is still possible to predict the parameters within a certain range of the strata ahead, even in the areas with a small number of adjacent wells and scanty logging data, and the velocity model can be dynamically adjusted, thereby significantly improving the accuracy of the velocity model. The present application achieves the comprehensive utilization of the drilling parameter, the logging parameter and the seismic data and gives full play to the advantages of various data, thereby providing abundant information sources for the construction and optimization of the first velocity model, and improving the overall accuracy of the velocity model. By means of the data analysis method and the intelligent time-series model, an implicit relationship between the drilling parameter and the velocity parameter measured in real time is revealed, and is used for optimizing the velocity model. The present application achieves the dynamic ahead-of-bit prediction in complex drilling scenarios without the logging parameters by deeply exploring the low-frequency correlation between the drilling parameters and the logging parameters. This technique effectively improves the accuracy and reliability of the formation velocity prediction by combining the real-time generated drilling information and the historical logging data, especially in areas with complex geological conditions and strong heterogeneity, the model can be ensured to reflect the changes in the strata in time, thereby providing a key data support for the subsequent optimization of the velocity model, and significantly reducing geological hazards. The present application forms a highly cooperative velocity model optimization and prediction system by comprehensively utilizing multi-source data in the drilling scenarios, including the seismic data, the drilling parameter and the logging parameter, and the system obviously improves the prediction accuracy of the geological features and the reliability of the model in situations where the conventional methods are difficult to make accurate predictions due to the strong heterogeneity of the underground media.

In an embodiment of the present application, an electronic device or a main control device can be divided into functional modules according to the above-mentioned method examples. For example, the functional modules may be divided corresponding to each function, or two or more functions may be integrated into one processing unit. The above-mentioned integrated unit may be implemented in a form of hardware, and may also be implemented in a form of software functional modules. It should be noted that the division of modules in the embodiments of the present application is illustrative, which is merely a logical function division and there may be other division methods in actual implementation.

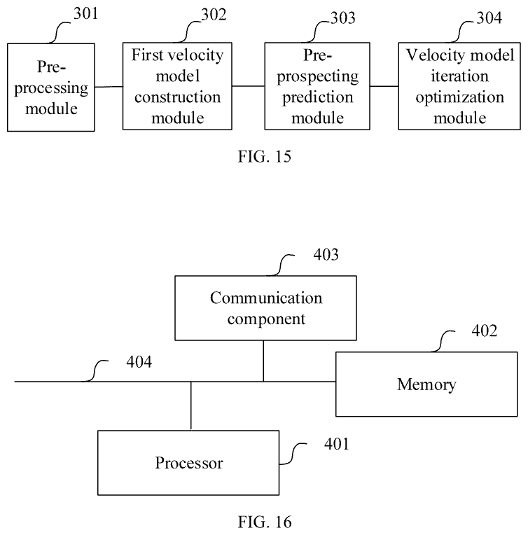

FIG. 15 is a schematic structural diagram of a model training apparatus according to an embodiment of the present application. As shown in FIG. 15, in this embodiment, the model training apparatus may be located in an electronic device. The model training device includes:
a pre-processing module 301 configured to pre-process a drilling parameter of an explored well, a logging parameter of the explored well, and a drilling parameter of a target drilling well, where the pre-processing includes data outlier processing and data smoothing filtering;
a first velocity model construction module 302 configured to construct a first velocity model according to the pre-processed logging parameter of the explored well;
an ahead-of-bit prediction module 303 configured to obtain a predictive drilling parameter according to the pre-processed drilling parameter of the target drilling well and the pre-processed drilling parameter of the explored well; and
a velocity model iteration optimization module 304 configured to perform a first-level iterative optimization on the first velocity model according to the predictive drilling parameter and seismic data of the explored well and the target drilling well.

The model training apparatus provided in this embodiment may execute the technical solution of the model training method embodiment shown in FIG. 1, and the implementation principles and technical effects thereof are similar to those of the model training method embodiment shown in FIG. 1, and will not be repeated herein.

At the same time, based on the model training apparatus provided in the previous embodiment, the model training apparatus provided in the present application is further refined.

In an implementation, in this embodiment, the first velocity model construction module 302 is specifically configured to:
obtain a first velocity parameter according to the pre-processed logging parameter of the explored well, and perform low-pass filtering processing on the first velocity parameter through a low-pass filtering formula so as to obtain a second velocity parameter, where the low-pass filtering formula is:

$${V}_{low} ( f ) = \{ \begin{matrix}V ( f ) , & if \vert f \vert \leq {f}_{c} \\ 0 , & if \vert f \vert > {f}_{c}\end{matrix}$$

where, V_{low}(f) is the second velocity parameter, V(f) is the first velocity parameter, and f_{c} is a cut-off frequency; and
obtain an interpolated velocity parameter according to the second velocity parameter, and obtain the first velocity model according to the interpolated velocity parameter.

In an implementation, when obtaining the interpolated velocity parameter according to the second velocity parameter, the first velocity model construction module 302 obtains the interpolated velocity parameter through an interpolation formula according to the second velocity parameter; and the interpolation formula is:

$$V ( x , y , z ) = {\sum }_{j = 1}^{n} {λ}_{j} {V}_{j}$$

where, V(x, y, z) is the interpolated velocity parameter, n is an amount of control points, Vⱼ is the second velocity parameter, λⱼ is an interpolation weight obtained through a weight formula; and the weight formula is:

$$\{ \begin{matrix}{\sum }_{j = 1}^{n} {λ}_{j} γ ( {d}_{ij} ) + μ = γ ( {d}_{i 0} ) \\ {\sum }_{j = 1}^{n} {λ}_{j} = 1\end{matrix}$$

where, γ(dᵢⱼ) is a semi-variogram of spatial correlation between the control points in a velocity parameter curve, γ(dᵢ₀) is a semi-variogram of spatial correlation between the control points and points to be interpolated in the velocity parameter curve, μ is a Lagrange number, and n is the amount of the control points.

In an implementation, in this embodiment, the ahead-of-bit prediction module 303 is specifically configured to:
obtain the predictive drilling parameter according to the pre-processed drilling parameter of the target drilling well and the pre-processed drilling parameter of the explored well.

In an implementation, the ahead-of-bit prediction module 303 obtains the predictive drilling parameter through an ahead-of-bit prediction formula indicated by a time-series forecasting model, according to pre-processed drilling parameters at a plurality of time points of the target drilling well and the pre-processed drilling parameter of the explored well; and the ahead-of-bit prediction formula is:

$${P}_{t + h} = F ( {P}_{t} , {P}_{t - 1} , … , {P}_{t - n} , H )$$

where, Pₜ₊ₕ is the predictive drilling parameter, F( ) is the time-series forecasting model, Pₜ is a pre-processed drilling parameter of the target drilling well at a current time point, Pₜ₋₁ is a pre-processed drilling parameter of the target drilling well at a time point relative to which the current time point has passed one time point, Pₜ₋ₙ is a pre-processed drilling parameter of the target drilling well at a time point relative to which the current time point has passed n time points, and H is the pre-processed drilling parameter of the explored well.

In an implementation, in this embodiment, the velocity model iteration optimization module 304 is specifically configured to:
perform a first-level iterative optimization on the first velocity model according to the predictive drilling parameter and seismic data of the explored well and the target drilling well.

In an implementation, when the velocity model iteration optimization module 304 performs the first-level iteration optimization on the first velocity model according to the predictive drilling parameter and the seismic data of the explored well and the target drilling well, a target optimization is any one optimization within the first-level iterative optimization;
for the target optimization, the performing the first-level iterative optimization on the first velocity model according to the predictive drilling parameter and the seismic data of the explored well and the target drilling well, includes:
optimizing the first velocity model according to the seismic data of the explored well and the target drilling well, and taking an optimization result as a second velocity model;
optimizing the second velocity model according to the predictive drilling parameter, and taking an optimization result as a first velocity model after the target optimization.

In an implementation, when optimizing the second velocity model according to the predictive drilling parameter, the velocity model iteration optimization module 304 is specifically configured to:
obtain a predictive velocity parameter according to the predictive drilling parameter and a mapping relationship between the predictive drilling parameter and the predictive velocity parameter;
optimize the second velocity model according to the predictive velocity parameter.

In an implementation, when obtaining the predictive velocity parameter according to the predictive drilling parameter and the mapping relationship, the velocity model iteration optimization module 304 obtains the predictive velocity parameter corresponding to the predictive drilling parameter through a prediction formula indicated by the mapping relationship; and the prediction formula is:

$${V}_{pred} = F ( {P}_{t + h} )$$

where, V_{pred} is the predictive velocity parameter, F( ) is a trained time-series intelligent model, and Pₜ₊ₕ is the predictive drilling parameter.

In an implementation, when optimizing the second velocity model according to the predictive velocity parameter, the velocity model iteration optimization module 304 obtains an optimized second velocity model through a second velocity model update formula according to the predictive velocity parameter and the second velocity model; and the second velocity model update formula is:

$${V}_{2} = initial ( {V}_{1} , {V}_{pred} )$$

where, V₂ is the optimized second velocity model, V₁ is the second velocity model, V_{pred} is the predictive velocity parameter, and initial is an update process of the second velocity model.

In an implementation, when optimizing the first velocity model according to the seismic data of the explored well and the target drilling well, and taking the optimization result as the second velocity model, the velocity model iteration optimization module 304 obtains the second velocity model through a first velocity model update formula according to the seismic data and the first velocity model; and the first velocity model update formula is:

$${V}_{1} = seismic ( V )$$

where, V₁ is the second velocity model, V is the first velocity model, and seismic is an update process of the first velocity model.

In an implementation, in this embodiment, the model training apparatus further includes:
a data correlation analysis module configured to establish the mapping relationship between the predictive drilling parameter and the predictive velocity parameter according to a data analysis approach and a machine learning algorithm.

The model training apparatus provided in this embodiment may execute the technical solution of the model training method embodiments shown in FIGS. 1 and 3, and the implementation principles and technical effects thereof are similar to those of the model training method embodiments shown in FIGS. 1 and 3, and will not be repeated herein.

According to embodiments of the present application, the present application further provides a model training electronic device, a computer-readable storage medium, and a computer program product.

FIG. 16 is a schematic structural diagram of an electronic device according to an embodiment of the present application. The model training electronic device refers to various electronic devices that can perform the model training method, such as microcomputers, single chip microcomputers, and other suitable computers. The components, their connections and relationships, and their functions shown in this application are merely exemplary and are not intended to limit implementation of the present application described and/or claimed herein.

As shown in FIG. 16, the electronic device includes at least one processor 401 and a memory 402. The electronic device further includes a communication component 403. The processor 401, the memory 402, and the communication component 403 are connected through a bus 404.

In a specific implementation process, the at least one processor 401 executes computer-executable instructions stored in the memory 402, so that the at least one processor 401 executes the model training method executed on the electronic device side as described above.

Reference for the specific implementation process of the processor 401 may be made to the above-mentioned model training method embodiments, and the implementation principles and technical effects thereof are similar, and will not be repeated herein.

In the above-mentioned embodiment, it should be understood that the processor 401 may be a central processing unit (CPU), and may also be another general processor, a digital signal processor (DSP), an application specific integrated circuit (ASIC), etc. The general processor 401 may be a microprocessor, or any conventional processor. The steps of the methods disclosed in the present application may be directly implemented by a hardware processor or by a combination of hardware and software modules in the processor.

The memory 402 may include a high-speed RAM memory, and may also include a non-volatile memory NVM, such as at least one disk memory.

The bus 404 may be an industry standard architecture (ISA) bus, a peripheral component (PCI) bus, an extended industry standard architecture (EISA) bus, etc. The bus 404 may be classified into an address bus, a data bus, a control bus, etc. For ease of representation, the bus 404 in the accompanying drawings of the present application is not limited to only one bus or one type of bus.

The foregoing description introduces the solution provided by the embodiments of the present application with respect to the functions implemented by the electronic device and the main control device. It can be understood that, in order to implement the foregoing functions, the electronic device or the main control device includes hardware structures and/or software modules that perform respective functions. In conjunction with the examples of units and algorithmic steps described in the embodiments of the present application, the embodiments of the present application may be implemented in the form of hardware or a combination of hardware and computer software. Whether a certain function is executed through hardware or computer software driving hardware depends on specific applications and design constraint conditions of the technical solution. Those skilled in the art may use different methods to implement the described functions for each specific application, but such implementations shall not be considered beyond the scope of the technical solution of the embodiments of the present application.

The present application further provides a computer-readable storage medium, where the computer-readable storage medium stores computer-executable instructions, and when the computer-executable instructions are executed by a processor, the model training method mentioned above is implemented.

The above-mentioned computer-readable storage medium can be implemented by any type of volatile or non-volatile storage device or a combination thereof, such as a static random access memory (SRAM), an electrically erasable programmable read-only memory (EEPROM), an erasable programmable read-only memory (EPROM), a programmable read-only memory (PROM), a read-only memory (ROM), a magnetic memory, a flash memory, a magnetic disk or an optical disk. The readable storage medium may be any available medium that can be accessed by a general purpose or special purpose computer.

An exemplary readable storage medium is coupled to the processor, so that the processor can read the information from the readable storage medium and can write information to the readable storage medium. The readable storage media can also be a component of the processor. The processor and the readable storage medium may be located in an application specific integrated circuit (ASIC). The processor and the readable storage medium may also be separate components in the electronic device or the main control device.

The memory 402 is a non-transitory computer-readable storage medium provided by the present application. The non-transitory computer readable storage medium of the present application stores computer instructions which are used to enable the computer to execute the model training method provided by the present application.

The memory 402, as the non-transitory computer-readable storage medium, may be configured to store non-transitory software programs, non-transitory computer-executable programs and modules, such as program instructions/modules corresponding to the model training method in the embodiments of the present application (e.g., the pre-processing module 301, the first velocity model construction module 302, the ahead-of-bit prediction module 303 and the velocity model iteration optimization module 304 shown in FIG. 15). The processor 401 executes various function applications and data processing by running the non-transitory software programs, instructions and modules stored in the memory 402, that is, implements the model training method in the above-mentioned method embodiments.

At the same time, the present embodiment further provides a computer program product, and when instructions in the computer program product are executed by a processor, the model training method of the described embodiments can be executed.

Those skilled in the art will easily come up with other embodiments of the present application after considering the specification and practicing the application disclosed herein. The present application is intended to cover any variations, uses, or adaptive changes of the present application, which follow the general principles of the present application and include common general knowledge or customary technical means in the art not disclosed in the present application. The specification and embodiments are only considered exemplary, and the true scope and spirit of the present application are indicated by the following claims.

It should be understood that embodiments of the present application are not limited to the precise structure described above and shown in the drawings, and various modifications and changes may be made without departing from the scope of the embodiments of the present application. The scope of the embodiments of the present application is limited only by the appended claims.

What is claimed is:

1. A model training method, comprising:
pre-processing a drilling parameter of an explored well, a logging parameter of the explored well, and a drilling parameter of a target drilling well, wherein the pre-processing comprises data outlier processing and data smoothing filtering;
constructing a first velocity model according to the pre-processed logging parameter of the explored well;
obtaining a predictive drilling parameter according to the pre-processed drilling parameter of the target drilling well and the pre-processed drilling parameter of the explored well; and
performing a first-level iterative optimization on the first velocity model according to the predictive drilling parameter and seismic data of the explored well and the target drilling well.

2. The model training method according to claim 1, wherein a target optimization is any one optimization within the first-level iterative optimization;
for the target optimization, the performing the first-level iterative optimization on the first velocity model according to the predictive drilling parameter and the seismic data of the explored well and the target drilling well, comprises:
optimizing the first velocity model according to the seismic data of the explored well and the target drilling well, and taking an optimization result as a second velocity model; and
optimizing the second velocity model according to the predictive drilling parameter, and taking an optimization result as a first velocity model after the target optimization.

3. The model training method according to claim 2, wherein before optimizing the second velocity model according to the predictive drilling parameter and taking the optimization result as the first velocity model after the target optimization, the method further comprises:
establishing a mapping relationship between the predictive drilling parameter and a predictive velocity parameter according to a data analysis approach and a machine learning algorithm;
for any one optimization, the optimizing the second velocity model according to the predictive drilling parameter, comprises:
obtaining the predictive velocity parameter according to the predictive drilling parameter and the mapping relationship; and
optimizing the second velocity model according to the predictive velocity parameter.

4. The model training method according to claim 3, wherein the obtaining the predictive velocity parameter according to the predictive drilling parameter and the mapping relationship, comprises:
obtaining the predictive velocity parameter corresponding to the predictive drilling parameter through a prediction formula indicated by the mapping relationship, wherein the prediction formula is:
$${V}_{pred} = F ( {P}_{t + h} )$$
wherein, V_{pred} is the predictive velocity parameter, F( ) is a trained time-series intelligent model, and Pₜ₊ₕ is the predictive drilling parameter.

5. The model training method according to claim 4, wherein the optimizing the second velocity model according to the predictive velocity parameter, comprises:
obtaining an optimized second velocity model through a second velocity model update formula according to the predictive velocity parameter and the second velocity model, wherein the second velocity model update formula is:
$${V}_{2} = initial ( {V}_{1} , {V}_{pred} )$$
wherein, V₂ is the optimized second velocity model, V₁ is the second velocity model, V_{pred} is the predictive velocity parameter, and initial is an update process of the second velocity model.

6. The model training method according to claim 2, wherein the optimizing the first velocity model according to the seismic data of the explored well and the target drilling well, and taking the optimization result as the second velocity model, comprises:
obtaining the second velocity model through a first velocity model update formula according to the seismic data and the first velocity model, wherein the first velocity model update formula is:
$${V}_{1} = seismic ( V )$$
wherein, V₁ is the second velocity model, V is the first velocity model, and seismic is an update process of the first velocity model.

7. The model training method according to claim 1, wherein the obtaining the predictive drilling parameter according to the pre-processed drilling parameter of the target drilling well and the pre-processed drilling parameter of the explored well, comprises:
obtaining the predictive drilling parameter through an ahead-of-bit prediction formula indicated by a time-series forecasting model, according to pre-processed drilling parameters at a plurality of time points of the target drilling well, and the pre-processed drilling parameter of the explored well, wherein the ahead-of-bit prediction formula is:
$${P}_{t + h} = F ( {P}_{t} , {P}_{t - 1} , … , {P}_{t - n} , H )$$
wherein, Pₜ₊ₕ is the predictive drilling parameter, F( ) is the time-series forecasting model, Pₜ is a pre-processed drilling parameter of the target drilling well at a current time point, Pₜ₋₁ is a pre-processed drilling parameter of the target drilling well at a time point relative to which the current time point has passed one time point, Pₜ₋ₙ is a pre-processed drilling parameter of the target drilling well at a time point relative to which the current time point has passed n time points, and H is the pre-processed drilling parameter of the explored well.

8. The model training method according to claim 1, wherein the constructing the first velocity model according to the pre-processed logging parameter of the explored well, comprises:
obtaining a first velocity parameter according to the pre-processed logging parameter of the explored well, and performing low-pass filtering processing on the first velocity parameter through a low-pass filtering formula so as to obtain a second velocity parameter, wherein the low-pass filtering formula is:
$${V}_{low} ( f ) = \{ \begin{matrix}V ( f ) , & if \vert f \vert \leq {f}_{c} \\ 0 , & if \vert f \vert > {f}_{c}\end{matrix}$$
wherein, V_{low}(f) is the second velocity parameter, V(f) is the first velocity parameter, and f_{c} is a cut-off frequency; and
obtaining an interpolated velocity parameter according to the second velocity parameter, and obtaining the first velocity model according to the interpolated velocity parameter.

9. The model training method according to claim 8, wherein the obtaining the interpolated velocity parameter according to the second velocity parameter, comprises:
obtaining the interpolated velocity parameter through an interpolation formula according to the second velocity parameter, wherein the interpolation formula is:
$$V ( x , y , z ) = {\sum }_{j = 1}^{n} {λ}_{j} {V}_{j}$$
wherein, V(x, y, z) is the interpolated velocity parameter, n is an amount of control points, Vⱼ is the second velocity parameter, λⱼ is an interpolation weight obtained through a weight formula, wherein the weight formula is:
$$\{ \begin{matrix}{\sum }_{j = 1}^{n} {λ}_{j} γ ( {d}_{ij} ) + μ = γ ( {d}_{i 0} ) \\ {\sum }_{j = 1}^{n} {λ}_{j} = 1\end{matrix}$$
wherein, γ(dᵢⱼ) is a semi-variogram of spatial correlation between the control points in a velocity parameter curve, γ(dᵢ₀) is a semi-variogram of spatial correlation between the control points and points to be interpolated in the velocity parameter curve, u is a Lagrange number, and n is the amount of the control points.

10. A model training apparatus, comprising a processor and a memory in communication connection with the processor; wherein
the memory stores computer-executable instructions; and
the processor executes the computer-executable instructions stored in the memory, so as enable the model training apparatus to perform the following steps:
pre-processing a drilling parameter of an explored well, a logging parameter of the explored well, and a drilling parameter of a target drilling well, wherein the pre-processing comprises data outlier processing and data smoothing filtering;
constructing a first velocity model according to the pre-processed logging parameter of the explored well;
obtaining a predictive drilling parameter according to the pre-processed drilling parameter of the target drilling well and the pre-processed drilling parameter of the explored well; and
performing a first-level iterative optimization on the first velocity model according to the predictive drilling parameter and seismic data of the explored well and the target drilling well.

11. The model training apparatus according to claim 10, wherein a target optimization is any one optimization within the first-level iterative optimization;
for the target optimization, the performing the first-level iterative optimization on the first velocity model according to the predictive drilling parameter and the seismic data of the explored well and the target drilling well, comprises:
optimizing the first velocity model according to the seismic data of the explored well and the target drilling well, and taking an optimization result as a second velocity model; and
optimizing the second velocity model according to the predictive drilling parameter, and taking an optimization result as a first velocity model after the target optimization.

12. The model training apparatus according to claim 11, wherein before optimizing the second velocity model according to the predictive drilling parameter and taking the optimization result as the first velocity model after the target optimization, the method further comprises:
establishing a mapping relationship between the predictive drilling parameter and a predictive velocity parameter according to a data analysis approach and a machine learning algorithm;
for any one optimization, the optimizing the second velocity model according to the predictive drilling parameter, comprises:
obtaining the predictive velocity parameter according to the predictive drilling parameter and the mapping relationship; and
optimizing the second velocity model according to the predictive velocity parameter.

13. The model training apparatus according to claim 12, wherein the obtaining the predictive velocity parameter according to the predictive drilling parameter and the mapping relationship, comprises:
obtaining the predictive velocity parameter corresponding to the predictive drilling parameter through a prediction formula indicated by the mapping relationship, wherein the prediction formula is:
$${V}_{pred} = F ( {P}_{t + h} )$$
wherein, V_{pred} is the predictive velocity parameter, F( ) is a trained time-series intelligent model, and Pₜ₊ₕ is the predictive drilling parameter.

14. The model training apparatus according to claim 13, wherein the optimizing the second velocity model according to the predictive velocity parameter, comprises:
obtaining an optimized second velocity model through a second velocity model update formula according to the predictive velocity parameter and the second velocity model, wherein the second velocity model update formula is:
$${V}_{2} = initial ( {V}_{1} , {V}_{pred} )$$
wherein, V₂ is the optimized second velocity model, V₁ is the second velocity model, V_{pred} is the predictive velocity parameter, and initial is an update process of the second velocity model.

15. The model training apparatus according to claim 11, wherein the optimizing the first velocity model according to the seismic data of the explored well and the target drilling well, and taking the optimization result as the second velocity model, comprises:
obtaining the second velocity model through a first velocity model update formula according to the seismic data and the first velocity model, wherein the first velocity model update formula is:
$${V}_{1} = seismic ( V )$$
wherein, V₁ is the second velocity model, V is the first velocity model, and seismic is an update process of the first velocity model.

16. The model training apparatus according to claim 10, wherein the obtaining the predictive drilling parameter according to the pre-processed drilling parameter of the target drilling well and the pre-processed drilling parameter of the explored well, comprises:
obtaining the predictive drilling parameter through an ahead-of-bit prediction formula indicated by a time-series forecasting model, according to pre-processed drilling parameters at a plurality of time points of the target drilling well, and the pre-processed drilling parameter of the explored well, wherein the ahead-of-bit prediction formula is:
$${P}_{t + h} = F ( {P}_{t} , {P}_{t - 1} , … , {P}_{t - n} , H )$$
wherein, Pₜ₊ₕ is the predictive drilling parameter, F( ) is the time-series forecasting model, Pₜ is a pre-processed drilling parameter of the target drilling well at a current time point, Pₜ₋₁ is a pre-processed drilling parameter of the target drilling well at a time point relative to which the current time point has passed one time point, Pₜ₋ₙ is a pre-processed drilling parameter of the target drilling well at a time point relative to which the current time point has passed n time points, and H is the pre-processed drilling parameter of the explored well.

17. The model training apparatus according to claim 10, wherein the constructing the first velocity model according to the pre-processed logging parameter of the explored well, comprises:
obtaining a first velocity parameter according to the pre-processed logging parameter of the explored well, and performing low-pass filtering processing on the first velocity parameter through a low-pass filtering formula so as to obtain a second velocity parameter, wherein the low-pass filtering formula is:
$${V}_{low} ( f ) = \{ \begin{matrix}V ( f ) , & if \vert f \vert \leq {f}_{c} \\ 0 , & if \vert f \vert > {f}_{c}\end{matrix}$$
wherein, V_{low}(f) is the second velocity parameter, V(f) is the first velocity parameter, and f_{c} is a cut-off frequency; and
obtaining an interpolated velocity parameter according to the second velocity parameter, and obtaining the first velocity model according to the interpolated velocity parameter.

18. The model training apparatus according to claim 17, wherein the obtaining the interpolated velocity parameter according to the second velocity parameter, comprises:
obtaining the interpolated velocity parameter through an interpolation formula according to the second velocity parameter, wherein the interpolation formula is:
$$V ( x , y , z ) = {\sum }_{j = 1}^{n} {λ}_{j} {V}_{j}$$
wherein, V(x, y, z) is the interpolated velocity parameter, n is an amount of control points, Vⱼ is the second velocity parameter, λⱼ is an interpolation weight obtained through a weight formula, wherein the weight formula is:
$$\{ \begin{matrix}{\sum }_{j = 1}^{n} {λ}_{j} γ ( {d}_{ij} ) + μ = γ ( {d}_{i 0} ) \\ {\sum }_{j = 1}^{n} {λ}_{j} = 1\end{matrix}$$
wherein, γ(dᵢⱼ) is a semi-variogram of spatial correlation between the control points in a velocity parameter curve, γ(dᵢ₀) is a semi-variogram of spatial correlation between the control points and points to be interpolated in the velocity parameter curve, μ is a Lagrange number, and n is the amount of the control points.

19. A non-transitory computer-readable storage medium, wherein the non-transitory computer-readable storage medium stores computer-executable instructions, so as to implement the following steps:
pre-processing a drilling parameter of an explored well, a logging parameter of the explored well, and a drilling parameter of a target drilling well, wherein the pre-processing comprises data outlier processing and data smoothing filtering;
constructing a first velocity model according to the pre-processed logging parameter of the explored well;
obtaining a predictive drilling parameter according to the pre-processed drilling parameter of the target drilling well and the pre-processed drilling parameter of the explored well; and
performing a first-level iterative optimization on the first velocity model according to the predictive drilling parameter and seismic data of the explored well and the target drilling well.
